(19) United States
(12) Patent Application Publication
(10) Pub. No.: US 2026/0223707 A1
(43) Pub. Date: Jul. 30, 2026

(54) CIRCUIT BOARD AND SEMICONDUCTOR PACKAGE COMPRISING SAME

(71) Applicant: LG INNOTEK CO., LTD., Seoul (KR)

(72) Inventors: Jin Ho SONG, Seoul (KR); Se Woong NA, Seoul (KR); Kee Han LEE, Seoul (KR)

(73) Assignee: LG INNOTEK CO., LTD., Seoul (KR)

(21) Appl. No.: 19/147,377

(22) PCT Filed: Jan. 15, 2024
(86) PCT No.: PCT/KR2024/000691

§ 371 Date: Jul. 11, 2025

(30) Foreign Application Priority Data
Jan. 13, 2023 (KR) 10-2023-0005620

(51) Int. Cl. H10W 70/685; H10B 80/00; H10D 80/30; H10W 70/60; H10W 70/63; H10W 90/00; H10W 90/10

(52) U.S. Cl. CPC H10W 70/687; H10W 70/611; H10W 70/635; H10B 80/00; H10D 80/30; H10W 90/10; H10W 90/724

(57) ABSTRACT

A circuit board according to an embodiment comprises an insulating layer; an electrode part disposed on the insulating layer; a protective layer disposed on the electrode part; and a plurality of conductive bonding parts disposed on the protective layer, wherein each of the plurality of conductive bonding parts includes a through electrode penetrating the protective layer, wherein an upper surface of the protective layer includes a concave surface provided between the plurality of through electrodes, and wherein a separation distance in a vertical direction between the concave surface and the electrode part is smaller than a thickness of at least one through electrode among the plurality of through electrodes.

### TECHNICAL FIELD

An embodiment relates to a circuit board and a semiconductor package including the same.

### BACKGROUND ART

As performances of electric/electronic products progresses, technologies for disposing a greater number of semiconductor devices on a semiconductor package circuit board of a limited size are being proposed and studied. However, since a general semiconductor package is based on mounting a single semiconductor device, there is a limit to obtaining a desired performance.

Accordingly, a semiconductor package that mounts a plurality of semiconductor devices using a plurality of circuit boards has been recently provided. This semiconductor package has a structure in which a plurality of semiconductor devices are connected to each other in a horizontal direction and/or a vertical direction on the circuit board. Accordingly, the semiconductor package has the advantage of efficiently using a mounting area of the semiconductor devices and transmitting high-speed signals through a short signal transmission path between the semiconductor devices.

In addition, semiconductor packages applied to products providing the Internet of Things (IoT), autonomous vehicles, and high-performance servers, etc. are increasing a number of semiconductor devices and/or a size of each semiconductor device due to a trend toward high integration. However, due to limitations of a reticle, etc., a concept is expanding to semiconductor chiplets in which functional parts of the semiconductor devices are divided.

Accordingly, an intercommunication between semiconductor devices and/or semiconductor chiplets is becoming important, and accordingly, there is a trend to dispose an interposer between the circuit board of the semiconductor package and the semiconductor devices.

An interposer can function as a redistribution layer that gradually increases a width or depth of a circuit pattern from the semiconductor device to the semiconductor package in order to facilitate the intercommunication between the semiconductor devices and/or semiconductor chiplets, or to interconnect the semiconductor devices and the semiconductor package circuit board, thereby smoothly transmitting electrical signals between the semiconductor device and the semiconductor package circuit board having a relatively large circuit pattern compared to the circuit pattern of the semiconductor device.

Meanwhile, as the number of input terminals and output terminals of semiconductor devices increases, miniaturization of a wiring and/or a bump is becoming important. Accordingly, a spacing between bumps is becoming narrower. In addition, the circuit board includes an electrode part electrically connected to a semiconductor device and/or a semiconductor chiplet, and a protective layer disposed on the electrode part. At this time, the electrode part, the protective layer, and the semiconductor device and/or the semiconductor chiplet are each made of different materials. Therefore, a coefficient of thermal expansion of the electrode part, a coefficient of thermal expansion of the protective layer, and a coefficient of thermal expansion of the semiconductor device and/or the semiconductor chiplet are different from each other.

A coefficient of thermal expansion of the protective layer is greater than coefficients of thermal expansion of the electrode part, the semiconductor device, and/or the semiconductor chiplet, and thus, it may expand and/or contract more than the electrode part and the semiconductor device and/or the semiconductor chiplet due to thermal stress applied in an usage environment of the semiconductor package.

In addition, if the protective layer is repeatedly expanded and/or contracted due to thermal stress, cracks may occur at electrical connection points between the electrode part and the semiconductor device and/or the semiconductor chiplet, and stress may be applied to a wiring or a bump having a fine pitch, which may cause problems such as cracks in the wiring or bumps, and as a result, mechanical reliability and/or electrical reliability of the semiconductor package may be deteriorated.

### DISCLOSURE

### Technical Problem

An embodiment provides a circuit board having a novel structure and a semiconductor package including the same.

In addition, the embodiment provides a circuit board capable of improving electrical connection reliability between semiconductor devices and a semiconductor package including the same.

In addition, the embodiment provides a circuit board including a protective layer capable of alleviating thermal deformation caused by thermal stress and a semiconductor package including the same.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

A circuit board according to an embodiment comprises an insulating layer; an electrode part disposed on the insulating layer; a protective layer disposed on the electrode part; and a plurality of conductive bonding parts disposed on the protective layer, wherein each of the plurality of conductive bonding parts includes a through electrode penetrating the protective layer, wherein an upper surface of the protective layer includes a concave surface provided between the plurality of through electrodes, and wherein a separation distance in a vertical direction between the concave surface and the electrode part is smaller than a thickness of at least one through electrode among the plurality of through electrodes.

In addition, each of the plurality of conductive bonding parts further includes a protruding electrode disposed on the through electrode.

In addition, a width of the concave surface in a horizontal direction is smaller than a separation spacing between the plurality of protruding electrodes.

In addition, the concave surface does not overlap with each of the protruding electrodes of the plurality of conductive bonding parts in the vertical direction.

In addition, a width of the concave surface in a horizontal direction is equal to a separation spacing between the plurality of protruding electrodes.

In addition, a width of the concave surface in a horizontal direction is greater than a separation spacing between the plurality of protruding electrodes.

In addition, the width of the concave surface in the horizontal direction is equal to the separation spacing between the plurality of through electrodes.

In addition, a protruding electrode of each of the plurality of conductive bonding parts includes a convex part overlapping the concave surface in the vertical direction and corresponding to the concave surface.

In addition, the concave surface includes a rounded surface from an upper surface to a lower surface of the protective layer.

In addition, a depth of the concave surface is smaller than the thickness of the through electrode.

In addition, a depth of the concave surface is same as the thickness of the through electrode.

In addition, a depth of the concave surface is greater than the thickness of the through electrode, and at least a portion of the concave surface is positioned lower than the upper surface of the electrode part.

Meanwhile, a semiconductor package according to an embodiment comprises the circuit board described above; a contact part disposed on a plurality of conductive bonding parts of the circuit board described above; and a semiconductor device attached to the contact part, wherein the concave surface overlaps the semiconductor device in a vertical direction.

In addition, the semiconductor package further includes a connection member embedded in the insulating layer, and the semiconductor device includes a first semiconductor device including a first terminal overlapping the connection member in a vertical direction; and a second semiconductor device spaced apart from the first semiconductor device in a horizontal direction and including a second terminal overlapping the connection member in the vertical direction.

In addition, the concave surface includes a first concave surface overlapped with the connection member in the vertical direction; and a second concave surface that does not overlap with the connection member in the vertical direction, and the first and second concave surfaces have different widths in the horizontal direction.

In addition, a width of the first concave surface in the horizontal direction is smaller than a width of the second concave surface in the horizontal direction.

In addition, at least a part of the electrode part is embedded in the insulating layer, and a contact member is embedded in the insulating layer and disposed between the electrode part and a pad part of the connection member.

### Advantageous Effects

The embodiment can improve mechanical reliability and/or physical reliability of a circuit board and a semiconductor package including the same.

Specifically, the semiconductor package includes an insulating layer, an electrode part disposed on the insulating layer, a protective layer disposed on the electrode part, and a plurality of conductive bonding parts disposed on the protective layer. In addition, each of the plurality of conductive bonding parts includes a through electrode penetrating the protective layer. In addition, an upper surface of the protective layer includes a concave surface provided between the plurality of through electrodes.

In addition, the concave surface provided at the upper surface of the protective layer can serve to buffer thermal deformation such as expansion and/or contraction of the protective layer due to thermal stress acting on the protective layer.

That is, the concave surface functions to increase a surface area of the upper surface of the protective layer. The concave surface functions to increase a surface area of the upper surface of the protective layer provided between the plurality of conductive bonding parts. Through this, the embodiment can solve an electrical open problem between the conductive bonding part, the contact part, and the semiconductor device that may occur due to thermal stress acting on the semiconductor package. For example, the embodiment can prevent cracks from occurring in the conductive bonding part and/or the electrode part by using the concave surface provided on the upper surface of the protective layer. In addition, the embodiment can prevent stress from being applied to the electrode part and/or the conductive bonding part having a fine pitch by using the concave surface provided on the upper surface of the protective layer. Through this, the embodiment can improve the mechanical reliability and/or the electrical reliability of the semiconductor package.

Specifically, when thermal stress is applied to the protective layer, thermal deformation such as expansion and/or contraction of the protective layer may occur, and the stress due to the thermal deformation of the protective layer may be transmitted to the conductive bonding part. Here, the thermal deformation may mean that a volume of the protective layer changes due to the expansion and/or contraction of the protective layer. In addition, when the stress due to the thermal deformation of the protective layer is continuously applied to the conductive bonding part, cracks may occur at a joint portion between the conductive bonding part and the electrode part, or a joint portion between the conductive bonding part and the contact part. This may cause an electrical open problem between the circuit board and the semiconductor device.

In contrast, the upper surface of the protective layer of the embodiment includes a concave surface provided between the conductive bonding parts. The concave surface provided on the upper surface of the protective layer can function to alleviate expansion and/or contraction of the protective layer due to thermal stress, and further minimize thermal deformation (e.g., volume change) of the protective layer due to thermal stress.

Therefore, the plurality of concave surfaces can minimize the stress generated by thermal stress from being transferred to the conductive bonding part, the contact part, and the semiconductor device. Accordingly, the embodiment can stably attach the semiconductor device to the circuit board, and thus improve mechanical reliability and electrical reliability between the circuit board and the semiconductor device. Furthermore, the embodiment can stably operate the semiconductor device, and thereby improve operational reliability of electronic products such as servers to which the semiconductor package is applied.

Furthermore, the protective layer, the conductive bonding part, and the semiconductor device are provided with different materials, and thus have different coefficients of thermal expansion. Therefore, due to a difference in the coefficient of thermal expansion between them, the thermal deformation of the protective layer having a relatively large coefficient of thermal expansion may be the largest. At this time, the embodiment can minimize thermal deformation such as expansion and/or contraction of the protective layer by providing a plurality of concave surfaces that buffer thermal deformation in the protective layer, thereby improving the mechanical reliability and/or electrical reliability of the semiconductor package.

In addition, the concave surface provided in the protective layer has a rounded surface from an upper surface to a lower surface of the protective layer. Through this, the embodiment can further improve an effect of preventing stress action by the concave surface. For example, when the concave surface has an angular square shape, stress may be concentrated at an angular portion of the concave surface, which may cause a problem of deterioration in mechanical reliability or electrical reliability. In contrast, the embodiment can provide the concave surface with a rounded surface, thereby preventing stress from being concentrated at a specific portion of the concave surface. Therefore, the embodiment can further improve the physical reliability and/or electrical reliability of the semiconductor package.

Meanwhile, the protective layer includes a plurality of first concave surfaces that overlap with the connection member in the vertical direction and a plurality of second concave surfaces that do not overlap with the connection member in the vertical direction. At this time, a width of the first concave surface in a horizontal direction is different from a width of the second concave surface in a horizontal direction. That is, the width of the first concave surface in the horizontal direction is smaller than the width of the second concave surface in the horizontal direction. Through this, the embodiment can prevent a height deviation between the plurality of conductive bonding parts by the first concave surface and the second concave surface, and further prevent a contact area between the through electrode of the conductive bonding part and the protective layer from being reduced. Therefore, the embodiment can improve the mechanical reliability and/or the electrical reliability of the semiconductor package. In addition, the embodiment can increase a surface area of the protective layer by making the width of the second concave surface larger than the width of the first concave surface, compared to a case where the width of the second concave surface is the same as the width of the first concave surface, and can maximize the effect of preventing stress due to thermal deformation.

In addition, the concave surface provided in the protective layer can solve an electrical short-circuit problem that may occur due to the contact part expanding in the horizontal direction according to the heat and pressure applied to the contact part. For example, when the contact part expands in the horizontal direction as the heat and pressure are applied to the contact part, the concave surface of the protective layer can function as a dam that prevents the expansion and movement of the contact part. Through this, the embodiment can further improve the electrical reliability of the semiconductor package.

### DESCRIPTION OF DRAWINGS

FIG. 1 is a cross-sectional view showing a semiconductor package according to a first embodiment.

FIG. 2 is an enlarged view showing an enlarged region A of a semiconductor package of FIG. 1.

FIG. 3 is an enlarged view of a first modified example showing an enlarged region A of the semiconductor package of FIG. 1.

FIG. 4 is an enlarged view of a second modified example showing an enlarged region A of the semiconductor package of FIG. 1.

FIG. 5 is an enlarged view of a third modified example showing an enlarged region A of the semiconductor package of FIG. 1.

FIG. 6 is an enlarged view of a fourth modified example showing an enlarged region A of the semiconductor package of FIG. 1.

FIG. 7 is a drawing showing a semiconductor package according to a second embodiment.

FIG. 8 is a drawing showing a semiconductor package according to a second embodiment.

FIGS. 9 to 17 are drawings showing a method of manufacturing the semiconductor package shown in FIG. 1 in order of processes.

### BEST MODE

Hereinafter, exemplary embodiments of the present invention will be described in detail with reference to the accompanying drawings, wherein like reference numerals are used to designate identical or similar elements, and redundant description thereof will be omitted. The suffix “module” and “portion” of the components used in the following description are only given or mixed in consideration of ease of preparation of the description, and there is no meaning or role to be distinguished as it is from one another. Also, in the following description of the embodiments of the present invention, a detailed description of related arts will be omitted when it is determined that the gist of the embodiments disclosed herein may be obscured. Also, the accompanying drawings are included to provide a further understanding of the invention, are incorporated in, and constitute a part of this description, and it should be understood that the invention is intended to cover all modifications, equivalents, or alternatives falling within the spirit and scope of the invention.

Terms including ordinals, such as first, second, etc., may be used to describe various components, but the elements are not limited to these terms. The terms are used only for distinguishing one component from another.

When a component is referred to as being “connected” or “contacted” to another component, it may be directly connected or joined to the other component, but it should be understood that other component may be present therebetween. When a component is referred to as being “directly connected” or “directly contacted” to another component, it should be understood that other component may not be present therebetween.

A singular representation includes plural representations, unless the context clearly implies otherwise.

In the present application, terms such as “including” or “having” are used to specify the presence of features, numbers, steps, operations, components, parts, or combinations thereof described in the description. However, it should be understood that the terms do not preclude the presence or addition of one or more other features, numbers, steps, operations, components, parts, or combinations thereof.

Hereinafter, embodiments of a present invention will be described in detail with reference to attached drawings.

### —Electronic Device—

Before describing the embodiment, an electronic device to which the semiconductor package of the embodiment is applied will be briefly described. The electronic device includes a main board (not shown). The main board may be physically and/or electrically connected to various components. For example, the main board may be connected to the semiconductor package of the embodiment. Various semiconductor devices may be mounted on the semiconductor package.

The semiconductor device may include an active device and/or a passive device. The active device may be a semiconductor chip in the form of an integrated circuit (IC) in which hundreds to millions of devices are integrated in one semiconductor device. The semiconductor device may be a logic chip, a memory chip, or the like. The logic chip may be a central processor (CPU), a graphics processor (GPU), or the like. For example, the logic chip may be an application processor (AP) chip including at least one of a central processor (CPU), a graphics processor (GPU), a digital signal processor, a cryptographic processor, a microprocessor and a microcontroller, or an analog-digital converter, an application-specific IC (ASIC), or the like, or a chip set comprising a specific combination of those listed so far.

The memory chip may be a stack memory such as HBM. The memory chip may also include a memory chip such as volatile memory (e.g., DRAM), non-volatile memory (e.g., ROM), flash memory, and the like.

In addition, the semiconductor device may be an integrated passive device (IPD). In addition, the semiconductor device may be a multilayer ceramic capacitor (MLCC) or a silicon-based capacitor.

On the other hand, a product group to which the semiconductor package of the embodiment is applied may be any one of CSP (Chip Scale Package), FC-CSP (Flip Chip-Chip Scale Package), FC-BGA (Flip Chip Ball Grid Array), POP (Package on Package) and SIP (System in Package), but is not limited thereto.

In addition, the electronic device may be a smart phone, a personal digital assistant, a digital video camera, a digital still camera, a vehicle, a high-performance server, a network system, computer, monitor, tablet, laptop, netbook, television, video game, smart watch, automotive, or the like. However, the embodiment is not limited thereto, and may be any other electronic device that processes data in addition to these.

### —Semiconductor Package—

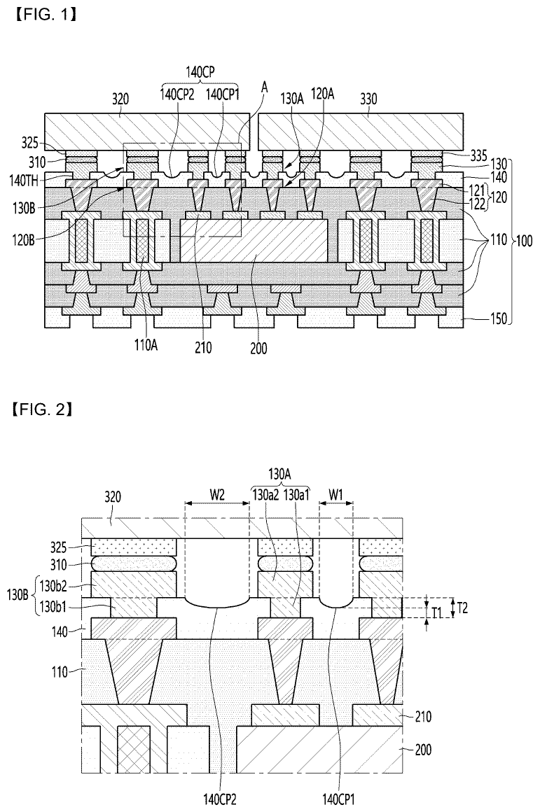

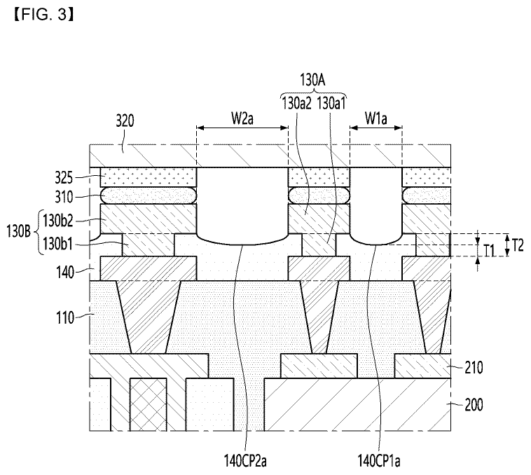

FIG. 1 is a cross-sectional view showing a semiconductor package according to a first embodiment, and FIG. 2 is an enlarged view showing an enlarged region A of a semiconductor package of FIG. 1.

Referring to FIGS. 1 and 2, the semiconductor package includes a circuit board 100.

The circuit board 100 in one embodiment means a package circuit board. For example, the circuit board 100 is disposed on the main circuit board of the electronic device and the semiconductor devices 320 and 330, and can electrically couple them therebetween. Specifically, the circuit board 100 can horizontally electrically connect the semiconductor devices 320 and 330 while vertically electrically connecting the semiconductor devices 320 and 330 and the main circuit board of the electronic device.

The circuit board 100 in another embodiment means a relay circuit board disposed between a package circuit board and the semiconductor devices 320 and 330. For example, the relay circuit board may mean an interposer. That is, the circuit board 100 may horizontally electrically connect between semiconductor devices 320 and 330 and vertically electrically connect between the semiconductor devices 320 and 330 and the package circuit board.

The semiconductor package includes semiconductor devices 320 and 330 electrically connected on the circuit board 100.

The semiconductor devices 320 and 330 may include a first semiconductor device 320 and a second semiconductor device 330, but are not limited thereto. As an example, three or more semiconductor devices may be disposed on the circuit board 100.

The semiconductor devices 320 and 330 include a contact part 310 disposed between the semiconductor devices 320 and 330 and the circuit board 100. The contact part 310 electrically connects terminals 325 and 335 of the semiconductor devices 320 and 330 and an electrode part of the circuit board 100.

The contact part 310 electrically connects the electrode part of the circuit board 100 and the terminals 325 and 335 of the semiconductor devices 320 and 330 by using at least one bonding method among a wire bonding, a solder bonding, and a direct metal bonding.

The wire bonding method means electrically connecting the electrode part of the circuit board 100 and the terminals 325 and 335 of the semiconductor devices 320 and 330 by using a conductor such as gold (Au).

The solder bonding method electrically connects the electrode part of the circuit board 100 and the terminals 325 and 335 of the semiconductor devices 320 and 330 by using a material including at least one of Sn, Ag, and Cu.

The direct bonding method between metals means applying heat and pressure between the electrode part of the circuit board 100 and the terminals 325 and 335 of the semiconductor devices 320 and 330 to recrystallize without the use of solder, wire, conductive adhesive, etc., thereby directly bonding the electrode part of the circuit board 100 and the terminals 325 and 335 of the semiconductor devices 320 and 330. In this case, the contact part 310 may mean a metal layer formed between the electrode part of the circuit board 100 and the terminals 325 and 335 of the semiconductor devices 320 and 330 by recrystallization.

For example, the contact part 310 may electrically connect the electrode part of the circuit board 100 and the terminals 325 and 335 of the semiconductor devices 320 and 330 by a thermal compression bonding method. The thermal compression bonding method can reduce a volume of the contact part 310 and prevent short circuits between multiple contact parts.

The semiconductor package includes a connection member 200 embedded in a circuit board 100.

The connection member 200 partially overlaps the semiconductor devices 320 and 330 disposed on the circuit board 100 in a vertical direction.

The connection member 200 electrically connects a part of the terminal 325 of the first semiconductor device 320 and a part of the terminal of the second semiconductor device 330.

A semiconductor device may be mounted on a circuit board 100 as a functionally separated chiplet unit, or multiple semiconductor devices having different functions, such as a CPU and GPU, or a GPU and HBM, and a connection member 200 may perform the function of horizontally electrically connecting them.

In addition, since widths of the electrode part provided in the circuit board 100 and the terminals 325 and 335 of the semiconductor devices 320 and 330 have a large difference from each other, a buffering role of the electrode pattern for electrical connection is required. Here, the buffering role may mean having a size between the width of the electrode part of the circuit board 100 and the width of the terminal of the semiconductor device. The connection member 200 may have a function of buffering the electrode pattern for electrical connection.

In one embodiment, the connection member 200 is an inorganic bridge. For example, the inorganic bridge may be a silicon bridge. For example, the connection member 200 may include a silicon circuit board and a redistribution layer.

In another embodiment, the connection member 200 is an organic bridge. For example, the connection member 200 may include an organic material. For example, the connection member 200 may include an organic circuit board in which the silicon circuit board of the inorganic bridge is replaced with an organic material.

The connection member 200 includes a pad part 210. The pad part 210 of the connection member 200 is electrically connected to the electrode part of the circuit board 100. In addition, the electrode part of the circuit board 100 is electrically connected to the terminals 325 and 335 of the semiconductor devices 320 and 330. Therefore, the connection member 200 electrically connects between the terminals 325 and 335 of the semiconductor devices 320 and 330.

The circuit board 100 electrically connected to the connection member 200 and the semiconductor devices 320 and 330 is specifically described as follows.

The circuit board 100 includes an insulating layer 110.

The insulating layer 110 may include an organic material that does not include a reinforcing member that enables excellent processability, slimming of the circuit board, and miniaturization of the electrode part 120 provided in the circuit board 100. For example, the insulating layer 110 of the circuit board 100 may use ABF (Ajinomoto Build-up Film), a product released by Ajinomoto Co., Ltd., and FR-4, BT (Bismaleimide Triazine), PID (Photo Image-able Dielectric resin), BT, etc.

The insulating layer 110 is provided in multiple layers.

The insulating layer 110 may be provided in an inner layer of the circuit board. Here, being provided in the inner layer means that another insulating layer (e.g., a protective layer) may be disposed on at least one of upper and lower portions of the insulating layer 110.

For example, the insulating layer 110 may be provided in four layers as shown in FIG. 1, but is not limited thereto.

In one embodiment, a plurality of layers of the insulating layer 110 may be provided with a same insulating material, but the embodiment is not limited thereto, and at least one layer among the plurality of layers of the insulating layer 110 may be provided with an insulating material different from at least other layers.

When the insulating layer 110 is provided with a plurality of layers, interfaces between the plurality of layers may not be easily distinguished. In this case, the distinction of the interfaces between the layers may be made by the electrode part 120 disposed in the insulating layer 110. The electrode part 120 includes a wiring electrode part 121 and a via electrode part 122. The wiring electrode part 121 is disposed at an interface between the plurality of layers of the insulating layer 110. The wiring electrode part 121 includes a pad and/or a trace, etc. In addition, the via electrode part 122 electrically connects the wiring electrode parts 121 disposed in different layers along a vertical direction. The via electrode part 122 includes a via electrode. At this time, a width of the wiring electrode part 121 in the horizontal direction is different from a width of the via electrode part 122 in the horizontal direction. Therefore, a difference between the width of the wiring electrode part 121 and the width of the via electrode part 122 in the horizontal direction can be used to distinguish the interface between the multiple layers of the insulating layer 110. In addition, a slope of a side surface of the wiring electrode part 121 is different from a slope of a side surface of the via electrode part 122. Therefore, a difference between the slope of the side surface of the wiring electrode part 121 and the slope of the side surface of the via electrode part 122 can be used to distinguish the interface between the multiple layers of the insulating layer 110.

However, even if the multiple layers of the insulating layer 110 include the same insulating material, the interfaces between the multiple layers can be distinguished.

Through the laminated structure of the insulating layer 110 described above, the circuit board 100 of the embodiment can electrically connect between the semiconductor devices 320 and 330 and the package circuit board and/or the main circuit board.

At least one layer of the multiple layers of the insulating layer 110 of one embodiment includes a reinforcing member. The reinforcing member in one embodiment may mean a glass fiber. In another embodiment, the reinforcing member may mean a GCP (Glass Core Primer). When the reinforcing member means the glass fiber, at least one layer of the multiple layers of the insulating layer 110 is provided as a core layer, and thus the circuit board 100 is provided as a core circuit board.

In addition, the rigidity of the circuit board 100 can be improved by at least one layer of the multiple layers of the insulating layer 110 including the reinforcing member. For example, the reinforcing member may have a function of preventing the circuit board 100 and the semiconductor package from being greatly bent in a specific direction. Accordingly, it is possible to prevent the insulating layer 110 from bending during a manufacturing process of the circuit board 100, thereby improving the positional accuracy of the electrode part 120, and further improving an alignment between them. In addition, as the rigidity of the circuit board 100 is secured, the semiconductor devices 320 and 330 can be coupled on the circuit board 100, and the semiconductor devices 320 and 330 can be operated stably. Furthermore, an electronic product such as a server to which the semiconductor package of the embodiment is applied can be operated stably, and thus the product reliability can be improved.

In addition, when at least one layer among the multiple layers of the insulating layer 110 includes a reinforcing member, a layer including the reinforcing member is provided with an insulating member 110A. The insulating member 110A penetrates the insulating layer including the reinforcing member. The insulating member 110A may be provided with hole plugging ink, but is not limited thereto. The insulating member 110A is surrounded by a via electrode part 122 of an electrode part 120 penetrating a layer including a reinforcing member. The insulating member 110A can solve electrical reliability problems and/or mechanical reliability problems that may occur due to a through hole of the layer including the reinforcing member not being entirely filled by the via electrode part 122.

The electrode part 120 of the circuit board 100 includes a wiring electrode part 121 and a via electrode part 122.

The wiring electrode part 121 can be horizontally disposed between each of the plurality of layers of the insulating layer 110, and the via electrode part 122 can be vertically disposed penetrating each of the plurality of layers of the insulating layer 110.

The electrode part 120 is divided into a plurality of groups. The electrode part 120 includes a first electrode part 120A that overlaps the semiconductor devices 320 and 330 and the connection member 200 in the vertical direction. In addition, the electrode part 120 includes a second electrode part 120B that overlaps the first electrode part 120A in the horizontal direction and does not overlap the connection member 200 in the vertical direction. The second electrode part 120B overlaps the semiconductor devices 320 and 330 in the vertical direction. That is, the first electrode part 120 is an electrode part that overlaps the connection member 200 and the semiconductor devices 320 and 330 in the vertical direction, respectively, and the second electrode part 120B is an electrode part that overlaps the semiconductor devices 320 and 330 in the vertical direction while not overlapping the connection member 200 in the vertical direction.

At least one of a width of a wiring electrode of the first electrode part 120A, a width of a via electrode of the first electrode part 120A, and a spacing between the plurality of wiring electrodes spaced apart in the horizontal direction of the first electrode part 120A may be different from a width of a wiring electrode of the second electrode part 120B, a width of a via electrode of the second electrode part 120B, and a spacing between a plurality of wiring electrodes spaced apart in the horizontal direction of the second electrode part 120B. For example, at least one of the width of the wiring electrode, the width of the via electrode, and the spacing between the plurality of wiring electrodes spaced apart in the horizontal direction of the first electrode part 120A may be smaller than the width of the wiring electrode, the width of the via electrode, and the spacing between the plurality of wiring electrodes spaced apart in the horizontal direction of the second electrode part 120B.

Through this, the embodiment can arrange both the wiring electrode and the via electrode of the first electrode part 120A within a limited space, and can stably electrically connect the semiconductor devices 320 and 330 and the connection member 200.

The circuit board 100 includes a conductive bonding part 130. The conductive bonding part 130 is disposed on the electrode part 120. For example, the conductive bonding part 130 is disposed on a wiring electrode part disposed on an uppermost side among the wiring electrode parts disposed on each layer of the insulating layer 110.

The conductive bonding part 130 penetrates a first protective layer 140 to be described later. The conductive bonding part 130 protrudes onto the first protective layer 140 to be described later. The conductive bonding part 130 may be referred to as a bump.

The conductive bonding part 130 protrudes onto the first protective layer 140 of the circuit board 100 to stably connect with the terminals 325 and 335 of the semiconductor devices 320 and 330 using the contact part 310. Accordingly, the conductive bonding part 130 can separate the contact part 310 and the circuit board 100 by a certain spacing, and improve a positional alignment between the conductive bonding part 130 and the terminals of the semiconductor devices 320 and 330.

The conductive bonding part 130 includes a through electrode penetrating the first protective layer 140 and a protruding electrode protruding onto the first protective layer 140. The through electrode of the conductive bonding part 130 is disposed on the electrode part 120 and penetrates the first protective layer 140. The through electrode of the conductive bonding part 130 may mean a region that overlaps the first protective layer 140 in a horizontal direction among an entire region in a thickness direction of the conductive bonding part 130.

The protruding electrode of the conductive bonding part 130 is disposed on the through electrode of the conductive bonding part 130. In addition, the protruding electrode of the conductive bonding part 130 is disposed on the first protective layer 140. For example, the protruding electrode of the conductive bonding part 130 is provided to extend in a horizontal direction on the through electrode of the conductive bonding part 130. For example, a width of the protruding electrode of the conductive bonding part 130 in the horizontal direction is greater than a width of the through electrode of the conductive bonding part 130 in the horizontal direction. Therefore, the protruding electrode of the conductive bonding part 130 includes a first region that overlaps the through electrode in the vertical direction, and a second region that overlaps the first protective layer 140 while not overlapping the through electrode in the vertical direction.

The conductive bonding part 130 is provided in multiple numbers. The conductive bonding part 130 is provided in multiple numbers and is spaced apart from the electrode part 120 in the horizontal direction. The conductive bonding part 130 includes a first conductive bonding part 130A disposed on a first electrode part 120A and a second conductive bonding part 130B disposed on a second electrode part 120B.

The first conductive bonding part 130A is provided between the first electrode part 120A disposed on the connection member 200 and terminals of the semiconductor devices 320 and 330. The second conductive bonding part 130B is provided between the second electrode part 120B and terminals of the semiconductor devices 320 and 330.

In addition, each of the first conductive bonding part 130A and the second conductive bonding part 130B includes a through electrode and a protruding electrode. The first conductive bonding part 130A includes a first through electrode 130a1 and a first protruding electrode 130a2. The second conductive bonding part 130B includes a second through electrode 130b1 and a second protruding electrode 130b2.

A spacing between a plurality of first through electrodes 130a1 of the first conductive bonding part 130A is different from a spacing between a plurality of second through electrodes 130b1 of the second conductive bonding part 130A. For example, a spacing between the plurality of first through electrodes 130a1 is smaller than a spacing between the plurality of second through electrodes 130b1. In addition, a spacing between the plurality of first protruding electrodes 130a2 of the first conductive bonding part 130A is different from a spacing between the plurality of second protruding electrodes 130b2 of the second conductive bonding part 130B. In addition, a spacing between the plurality of first protruding electrodes 130a2 of the first conductive bonding part 130A is smaller than a spacing between the plurality of second protruding electrodes 130b2 of the second conductive bonding part 130B. That is, the first conductive bonding part 130A is connected to terminals of the semiconductor devices 320 and 330 having a relatively fine width and/or fine pitch. In addition, the second conductive bonding part 130B is connected to terminals of the semiconductor devices 320 and 330 having a relatively large width and/or large pitch compared to the first conductive bonding part 130A. Therefore, the embodiment allows a spacing between the first through electrodes 130a1 of the plurality of first conductive bonding parts 130A to be smaller than a spacing between the second through electrodes 130b1 of the plurality of second conductive bonding parts 130B, thereby stably connecting the connection member 200 and the semiconductor devices 320 and 330.

The circuit board 100 includes a protective layer. The protective layer includes a first protective layer 140 disposed on the insulating layer 110 and a second protective layer 150 disposed under the insulating layer 110.

The first protective layer 140 functions to protect an upper surface of the insulating layer 110 and a wiring electrode part 121 disposed at an uppermost side of the insulating layer 110. The second protective layer 150 functions to protect the lower surface of the insulating layer 110 and the wiring electrode part disposed at a lowermost side of the insulating layer 110.

In one embodiment, the first protective layer 140 and the second protective layer 150 may include a same insulating material as the insulating layer 110.

In another embodiment, the first protective layer 140 and the second protective layer 150 may include an insulating material different from the insulating layer 110, and may be, for example, a solder resist.

The first protective layer 140 and the second protective layer 150 may be solder resist layers including organic polymer materials. For example, the first protective layer 140 and the second protective layer 150 may include an epoxy acrylate series resin. In addition, the first protective layer 140 and the second protective layer 150 may include a resin, a curing agent, a photoinitiator, a pigment, a solvent, a filler, an additive, an acrylic series monomer, etc. However, the embodiment is not limited thereto, and the first protective layer 140 and the second protective layer 150 may be any one of a photo solder resist layer, a cover-lay, and a polymer material.

The upper surface of the first protective layer 140 includes a concave surface 140CP.

The concave surface 140CP is provided between a plurality of conductive bonding parts 130.

The concave surface 140CP is provided concavely from an upper surface of the first protective layer 140 toward a lower surface. In addition, the concave surface 140CP is provided on an upper surface of the first protective layer 140 provided between a plurality of conductive bonding parts 130. For example, the concave surface 140CP is provided between the through electrodes of the plurality of conductive bonding parts 130. In addition, the concave surface 140CP can prevent stress due to thermal deformation from being transmitted to the conductive bonding part 130, and in particular, can prevent stress from being transmitted to the through electrode of the conductive bonding part 130 having a relatively small width.

The concave surface 140CP has a function of increasing a surface area of the upper surface of the first protective layer 140. The concave surface 140CP functions to increase a surface area of the upper surface of the first protective layer 140 provided between the plurality of conductive bonding parts 130. That is, when the concave surface 140CP is provided on the upper surface of the first protective layer 140, a surface area between the plurality of conductive bonding parts 130 can be increased according to a width in the horizontal direction and a depth in the vertical direction of the concave surface 140CP compared to a case where an upper surface of the first protective layer 140 is a flat surface.

Through this, the embodiment can solve an electrical open problem between the conductive bonding part 130, the contact part 310, and the semiconductor devices 320 and 330, which may be caused by thermal stress acting on the semiconductor package. For example, the embodiment can prevent cracks from occurring in the conductive bonding part 130 and/or the electrode part 120 by using the concave surface 140CP provided on the upper surface of the first protective layer 140. In addition, the embodiment can prevent stress from being applied to the electrode part 120 and/or the conductive bonding part 130 having a fine pitch by using the concave surface 140CP provided on the upper surface of the first protective layer 140. Through this, the embodiment can improve the mechanical reliability and/or electrical reliability of the semiconductor package.

Specifically, the semiconductor devices 320 and 330 is electrically connected to the conductive bonding part 130 through the contact part 310. In addition, the conductive bonding part 130 protrudes onto the first protective layer 140 while penetrating the first protective layer 140.

At this time, when thermal stress is applied to the first protective layer 140, thermal deformation such as expansion and/or contraction of the first protective layer 140 may occur, and stress due to the thermal deformation of the first protective layer 140 may be applied to the conductive bonding part 130 penetrating the first protective layer 140. The thermal deformation may mean that a volume of the first protective layer 140 changes due to expansion and/or contraction of the first protective layer 140.

If the thermal deformation of the first protective layer 140 is repeated, stress may be applied to the conductive bonding part 130 disposed in the first protective layer 140, and a crack may occur in an electrical connection portion between the conductive bonding part 130 and the electrode part 120 due to the stress. As a result, the conductive bonding part 130 may be peeled off from the electrode part 120, which may cause mechanical reliability and/or electrical reliability problems.

In addition, if the thermal deformation of the first protective layer 140 is repeated, stress may be applied to the contact part 310 disposed on the conductive bonding part 130, and as a result, a crack may occur in the contact part 310. As a result, an electrical open problem may occur between the semiconductor devices 320 and 330 and the conductive bonding part 130.

The concave surface 140CP provided on the upper surface of the first protective layer 140 functions to increase the surface area of the upper surface of the first protective layer 140, and thus can reduce a degree of thermal deformation (e.g., degree of expansion and/or degree of contraction) of the first protective layer 140 caused by thermal stress. Through this, the concave surface 140CP provided on the upper surface of the first protective layer 140 can prevent stress caused by thermal deformation of the first protective layer 140 from acting on the conductive bonding part 130. For example, the concave surface 140CP can relieve stress caused by thermal stress and prevent the stress from being transmitted in a direction toward the conductive bonding part 130.

In addition, the concave surface 140CP can prevent the shock due to stress from being transmitted to the terminals 325 and 335 of the conductive bonding part 130, the contact part 310, and the semiconductor devices 320 and 330.

Therefore, the embodiment can stably attach the semiconductor devices 320 and 330 to the circuit board 100, and thereby improve the mechanical reliability and electrical reliability between the circuit board 100 and the semiconductor devices 320 and 330. Furthermore, the embodiment can stably operate the semiconductor devices 320 and 330, and thereby improve the operational reliability of electronic products such as servers to which the semiconductor package is applied.

In addition, the concave surface 140CP is provided with a rounded surface from the upper surface to the lower surface of the first protective layer 140. Through this, the embodiment can further improve a stress-prevention effect by the concave surface 140CP. For example, when the concave surface 140CP has an angular square shape, stress can be concentrated at an angular portion, which can cause a problem of reduced mechanical reliability or reduced electrical reliability. In contrast, the embodiment can allow the concave surface 140CP to have a rounded curve, thereby preventing stress from being concentrated at a specific portion of the concave surface 140CP. Therefore, the embodiment can further improve the physical reliability and/or electrical reliability of the semiconductor package.

In addition, the first protective layer 140, the conductive bonding part 130, and the semiconductor devices 320 and 330 have different materials. For example, the first protective layer 140 may be formed of a solder resist, the conductive bonding part 130 may be formed of a metal material such as copper, and the semiconductor devices 320 and 330 may be formed of a silicon material. In this case, coefficients of thermal expansion of the first protective layer 140, the conductive bonding part 130, and the semiconductor devices 320 and 330 are different from each other. For example, the coefficient of thermal expansion of the first protective layer 140 is greater than the coefficients of thermal expansion of the conductive bonding part 130 and the semiconductor devices 320 and 330. Therefore, when the same thermal stress is applied to the first protective layer 140, the conductive bonding part 130, and the semiconductor devices 320 and 330, the degree of thermal deformation of the first protective layer 140 may be the greatest compared to the conductive bonding part 130 and the semiconductor devices 320 and 330.

Therefore, the embodiment can prevent stress due to thermal deformation such as expansion and/or contraction from acting on the electrical joint between the circuit board 100 and the semiconductor devices 320 and 330 by providing a concave surface 140CP on the upper surface of the first protective layer 140, thereby improving the mechanical reliability and/or electrical reliability of the semiconductor package.

In addition, the concave surface 140CP of the first protective layer 140 is provided with a certain depth on the upper surface of the first protective layer 140. At this time, a depth of the concave surface 140CP is smaller than a thickness of the first protective layer 140 in a region that does not overlap with the electrode part 120 in the vertical direction. For example, the concave surface 140CP does not penetrate the first protective layer 140 in a region that does not overlap with the electrode part 120 in the vertical direction.

The concave surface 140CP is separated from the electrode part 130 disposed on the insulating layer 110 in the vertical direction. For example, the concave surface 140CP has a separation distance T1 in the vertical direction from the electrode part 130 disposed on the insulating layer 110. At this time, the separation distance T1 in the vertical direction between the electrode part 130 and the concave surface 140CP is smaller than a thickness of the through electrode of the conductive bonding part 130. If the separation distance T1 in the vertical direction between the electrode part 130 and the concave surface 140CP is greater than the thickness of the through electrode of the conductive bonding part 130, the stress prevention effect exhibited by the concave surface 140CP may be insufficient, and as a result, stress due to thermal deformation may be applied to the conductive bonding part 130.

The concave surface 140CP is provided between each of the plurality of conductive bonding parts 130. At this time, the concave surfaces 140CP of the first protective layer 140 have different widths in the horizontal direction and are provided in multiple numbers.

The concave surface 140CP includes a first concave surface 140CP1 provided between the plurality of first conductive bonding parts 130A. In addition, the concave surface 140CP includes a second concave surface 140CP2 provided between the plurality of second conductive bonding parts 130B. The second concave surface 140CP2 is provided between the first conductive bonding part 130A and the second conductive bonding part 130B that are provided adjacent to each other.

For example, the first concave surface 140CP1 overlaps the connection member 200 in the vertical direction. In addition, the second concave surface 140CP2 does not overlap with the connection member 200 in the vertical direction.

At this time, a width W1 in the horizontal direction of the first concave surface 140CP1 is different from a width W2 in the horizontal direction of the second concave surface 140CP2. For example, the width W1 in the horizontal direction of the first concave surface 140CP1 is smaller than the width W2 in the horizontal direction of the second concave surface 140CP2.

That is, the first concave surface 140CP1 is provided between a plurality of first through electrodes 130a1 of the first conductive bonding part 130A having a relatively fine pitch. In addition, the second concave surface 140CP2 is provided between a plurality of second through electrodes 130b1 of the second conductive bonding part 130B having a relatively large pitch. Therefore, the embodiment allows the width of the horizontal direction of the first concave surface 140CP1 to be different from the width of the horizontal direction of the second concave surface 140CP2. Therefore, the embodiment can solve a problem of physical stiffness degradation that occurs due to the decrease in the contact area between the through electrode and the first protective layer 140 by the first concave surface 140CP1 and the second concave surface 140CP2 in a process of forming the conductive bonding part 130, particularly, the process of forming the through electrode of the conductive bonding part 130.

In addition, the first concave surface 140CP1 and the second concave surface 140CP2 of the first protective layer 140 can solve an electrical problem of electrically short-circuiting a plurality of adjacent conductive bonding parts 130 due to the diffusion of the contact part 310 disposed on the conductive bonding part 130. For example, when heat and pressure are applied to a contact part 310 disposed on a conductive bonding part 130 and the contact part 310 expands in the horizontal direction, the first concave surface 140CP1 and the second concave surface 140CP2 of the first protective layer 140 can function as a dam that prevents the contact part 310 from expanding and/or moving in the horizontal direction. Through this, the embodiment can further improve the electrical reliability of the semiconductor package.

Hereinafter, various examples of modifications of the concave surface provided in the protective layer will be described

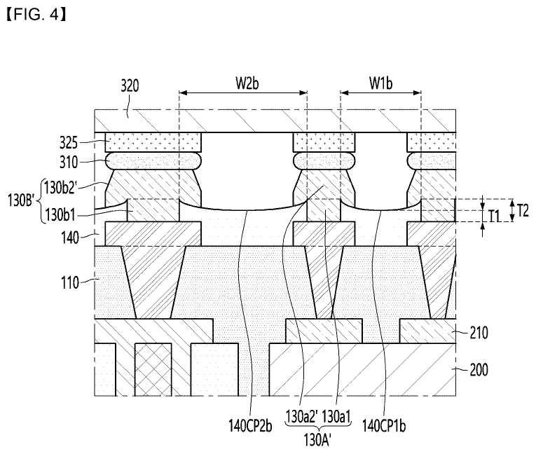

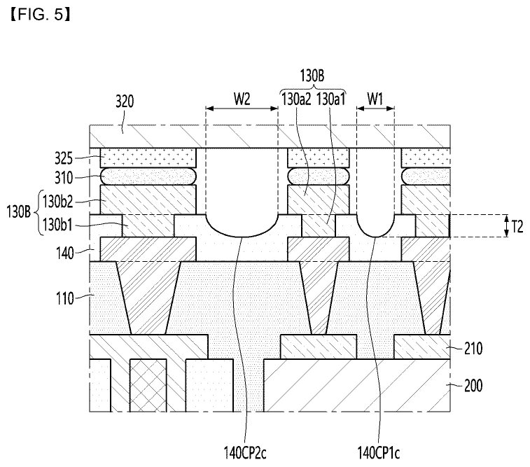

FIG. 3 is an enlarged view of a first modified example showing an enlarged region A of the semiconductor package of FIG. 1, FIG. 4 is an enlarged view of a second modified example showing an enlarged region A of the semiconductor package of FIG. 1, FIG. 5 is an enlarged view of a third modified example showing an enlarged region A of the semiconductor package of FIG. 1, and FIG. 6 is an enlarged view of a fourth modified example showing an enlarged region A of the semiconductor package of FIG. 1.

First, a width of each of the first concave surface 140CP1 and the second concave surface 140CP2 of FIG. 2 in the horizontal direction is smaller than a separation spacing between the plurality of conductive bonding parts 130 in the horizontal direction. For example, the width of each of the first concave surface 140CP1 and the second concave surface 140CP2 of FIG. 2 in the horizontal direction is smaller than the separation spacing between the plurality of protruding electrodes of the conductive bonding part 130.

Referring to FIG. 3, a width W1a of the first concave surface 140CP1a is equal to a separation spacing between the first protruding electrodes 130a2 of the first conductive bonding part 130A. In addition, a width W2a of the second concave surface 140CP2a is equal to a separation spacing between the second protruding electrodes 130b2 of the second conductive bonding part 130B. Therefore, each of the first concave surface 140CP1a and the second concave surface 140CP2a is entirely provided on the upper surface of the first protective layer 140 that does not vertically overlap with the protruding electrodes of the conductive bonding part 130. Through this, the first modified example of FIG. 3 can further increase a width in the horizontal direction of the concave surface compared to FIG. 2, thereby further increasing the surface area of the first protective layer 140, thereby further improving the physical reliability and/or electrical reliability of the semiconductor package.

Referring to FIG. 4, a width W1b of the first concave surface 140CP1b is larger than a separation spacing between the first protruding electrodes 130a2′ of the first conductive bonding part 130A. For example, the width W1b of the first concave surface 140CP1b is equal to the separation spacing between the first protruding electrodes 130a2′ of the first conductive bonding part 130A. Accordingly, the first protruding electrode 130a2′ of the first conductive bonding part 130 overlaps the first concave surface 140CP1b provided in the first protective layer 140 in the vertical direction. For example, the first protruding electrode 130a2′ of the first conductive bonding part 130A is in contact with the first concave surface 140CP1b. For example, the first protruding electrode 130a2′ of the first conductive bonding part 130A includes a convex part in contact with the first concave surface 140CP. Through this, the embodiment can increase a contact area between the first conductive bonding part 130A and the first protective layer 140 by allowing the convex part of the first protruding electrode 130a2′ of the first conductive bonding part 130A to be in contact with the first concave surface 140CP1b of the first protective layer 140. Through this, the embodiment can improve a bonding strength of the first conductive bonding part 130A and the first protective layer 140. For example, the convex part of the first protruding electrode 130a2′ of the first conductive bonding part 130A can function as an anchor that increases the bonding strength with the first protective layer 140.

In addition, the width W2b of the second concave surface 140CP2b is larger than the separation spacing between the second protruding electrodes 130b2′ of the second conductive bonding part 130B. For example, the width W2b of the second concave surface 140CP2b is equal to the separation spacing between the second protruding electrodes 130b2′ of the second conductive bonding part 130B. Accordingly, the second protruding electrode 130b2′ of the second conductive bonding part 130B overlaps the second concave surface 140CP2b provided in the first protective layer 140 in the vertical direction. For example, the second protruding electrode 130b2′ of the second conductive bonding part 130B is in contact with the second concave surface 140CP2b. For example, the second protruding electrode 130b2′ of the second conductive bonding part 130B includes a convex part in contact with the second concave surface 140CP2b. Through this, the embodiment can increase the contact area between the second conductive bonding part 130B and the first protective layer 140 by allowing the convex part of the second protruding electrode 130b2′ of the second conductive bonding part 130B to be in contact with the second concave surface 140CP2b of the first protective layer 140. Through this, the embodiment can improve the bonding strength between the second conductive bonding part 130B and the first protective layer 140. For example, the convex part of the second protruding electrode 130b2′ of the second conductive bonding part 130B may function as an anchor to increase the bonding strength with the first protective layer 140.

Referring to FIG. 5, the first protective layer 140 includes a first concave surface 140CP1c and a second concave surface 140CP2c. Each of the first concave surface 140CP1c and the second concave surface 140CP2c may have a greater depth than the concave surface of FIG. 2.

For example, depths of the first concave surface 140CP1c and the second concave surface 140CP2c of the first protective layer 140 are the same as a thickness T2 of the through electrode of the conductive bonding part 130. Through this, the embodiment can further maximize the effect exhibited by the first concave surface 140CP1c and the second concave surface 140CP2c, and further improve the degree of design freedom through the change in the depth of the concave surface.

Referring to FIG. 6, the first protective layer 140 includes the first concave surface 140CP1d and the second concave surface 140CP2d. Each of the first concave surface 140CP1d and the second concave surface 140CP2d can have a greater depth than the concave surface of FIG. 2.

For example, the depth T3 of the first concave surface 140CP1d and the second concave surface 140CP2d of the first protective layer 140 is greater than the thickness T2 of the through electrode of the conductive bonding part 130. For example, at least a portion of the first concave surface 140CP1d and the second concave surface 140CP2d is positioned lower than the upper surface of the electrode part 130. Through this, the embodiment can further maximize the effect of the first concave surface 140CP1d and the second concave surface 140CP2d, and further improve the degree of design freedom through the change in the depth of the concave surface.

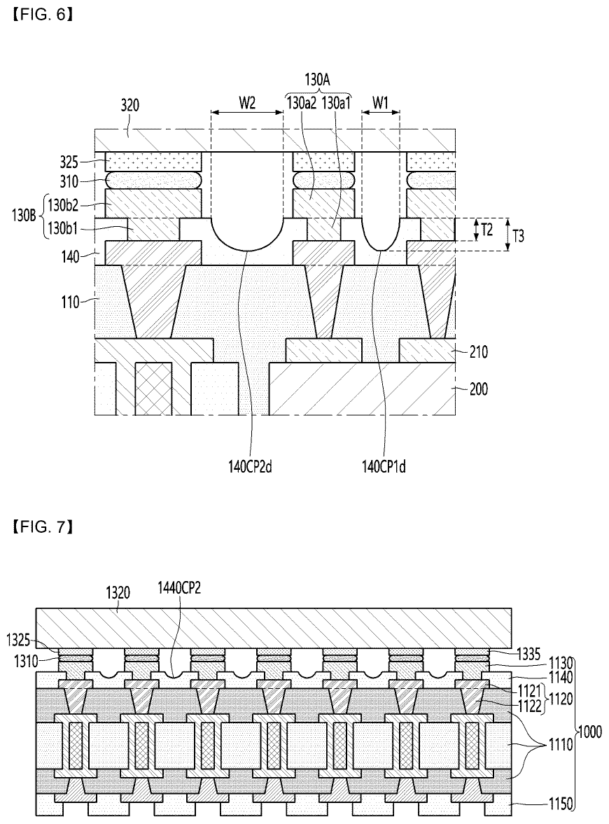

FIG. 7 is a drawing showing a semiconductor package according to a second embodiment.

Referring to FIG. 7, the semiconductor package of the second embodiment may have a structure in which the connection member 200 is omitted compared to the semiconductor package of the first embodiment.

The semiconductor package of the second embodiment includes a circuit board 1100 including an insulating layer 1110, an electrode part 1120, a conductive bonding part 1130, a first protective layer 1140, and a second protective layer 1150. In addition, the upper surface of the first protective layer 1140 includes a concave surface 1440CP2 provided between a plurality of conductive bonding parts 1130.

In addition, the semiconductor package includes a contact part 1310 and a semiconductor device 1320 disposed on the conductive bonding part 1130 of the circuit board 1100.

For example, the circuit board 1100 of the semiconductor package of the second embodiment may be a 2D circuit board, through which at least one semiconductor device 320 may be disposed on the circuit board 1100 without including a connection member 200 embedded in the circuit board 1100.

FIG. 8 is a drawing showing a semiconductor package according to a third embodiment.

Referring to FIG. 8, the semiconductor package of the third embodiment may have a different structure of a circuit board 2100 compared to the semiconductor package of the first embodiment.

The semiconductor package of the third embodiment includes a circuit board 2100 including an insulating layer 2110, an electrode part 2120, a conductive bonding part 2130, a first protective layer 2140, and a second protective layer 2150. In addition, an upper surface of the first protective layer 2140 includes a concave surface 2440CP2 provided between a plurality of conductive bonding parts 2130.

In addition, the semiconductor package includes a contact part 2310 and a semiconductor device 2320 disposed on the conductive bonding part 2130 of the circuit board 2100.

In addition, the semiconductor package includes a connection member 2200 embedded in the insulating layer 2110 of the circuit board 2100. In addition, the semiconductor package further includes a second contact part 2230 embedded in the insulating layer 2110 and electrically connecting the pad part 2210 and the electrode part 2120 of the connection member 2200.

For example, the circuit board of the first embodiment of FIG. 1 may be a core circuit board, and the circuit board of FIG. 8 may be a core-less circuit board.

In addition, each of uppermost and lowermost wiring electrode parts 121 provided in the circuit board of the first embodiment of FIG. 1 may be provided so as to protrude above and below the insulating layer 110.

In contrast, one of uppermost and lowermost wiring electrode parts provided in the circuit board of the third embodiment of FIG. 8 may have a structure embedded in the insulating layer 2110. For example, the circuit board 2100 may have an ETS (Embedded Trace Substrate) structure.

That is, the circuit board 2100 includes an electrode part 2120 disposed on a connection member 2200. The electrode part 2120 includes a first electrode part that overlaps the connection member 2200 in a vertical direction and a second electrode part that overlaps the first electrode part in a horizontal direction and does not overlap the connection member 2200 in a vertical direction.

In addition, at least a portion of each of the first electrode part and the second electrode part is embedded in an insulating layer 2110. Here, being embedded may mean that at least a portion of the side surface of the first electrode part and the second electrode part is covered with the insulating layer 2110. However, in FIG. 8, side surfaces of the first electrode part and the second electrode part are illustrated as being entirely covered with the insulating layer 2110, but is not limited thereto. For example, a portion of the side surfaces of the first electrode part and the second electrode part may be covered with an insulating layer 2110, and a remaining portion of the side surfaces of the first electrode part and the second electrode part may be covered with a first protective layer 2140, a conductive bonding part 2130, or a separate metal layer between the conductive bonding part 2130 and the electrode part.

The embodiment can improve mechanical reliability and/or physical reliability of a circuit board and a semiconductor package including the same.

Specifically, the semiconductor package includes an insulating layer, an electrode part disposed on the insulating layer, a protective layer disposed on the electrode part, and a plurality of conductive bonding parts disposed on the protective layer. In addition, each of the plurality of conductive bonding parts includes a through electrode penetrating the protective layer. In addition, an upper surface of the protective layer includes a concave surface provided between the plurality of through electrodes.

In addition, the concave surface provided at the upper surface of the protective layer can serve to buffer thermal deformation such as expansion and/or contraction of the protective layer due to thermal stress acting on the protective layer.

That is, the concave surface functions to increase a surface area of the upper surface of the protective layer. The concave surface functions to increase a surface area of the upper surface of the protective layer provided between the plurality of conductive bonding parts. Through this, the embodiment can solve an electrical open problem between the conductive bonding part, the contact part, and the semiconductor device that may occur due to thermal stress acting on the semiconductor package. For example, the embodiment can prevent cracks from occurring in the conductive bonding part and/or the electrode part by using the concave surface provided on the upper surface of the protective layer. In addition, the embodiment can prevent stress from being applied to the electrode part and/or the conductive bonding part having a fine pitch by using the concave surface provided on the upper surface of the protective layer. Through this, the embodiment can improve the mechanical reliability and/or the electrical reliability of the semiconductor package.

Specifically, when thermal stress is applied to the protective layer, thermal deformation such as expansion and/or contraction of the protective layer may occur, and the stress due to the thermal deformation of the protective layer may be transmitted to the conductive bonding part. Here, the thermal deformation may mean that a volume of the protective layer changes due to the expansion and/or contraction of the protective layer. In addition, when the stress due to the thermal deformation of the protective layer is continuously applied to the conductive bonding part, cracks may occur at a joint portion between the conductive bonding part and the electrode part, or a joint portion between the conductive bonding part and the contact part. This may cause an electrical open problem between the circuit board and the semiconductor device.

In contrast, the upper surface of the protective layer of the embodiment includes a concave surface provided between the conductive bonding parts. The concave surface provided on the upper surface of the protective layer can function to alleviate expansion and/or contraction of the protective layer due to thermal stress, and further minimize thermal deformation (e.g., volume change) of the protective layer due to thermal stress.

Therefore, the plurality of concave surfaces can minimize the stress generated by thermal stress from being transferred to the conductive bonding part, the contact part, and the semiconductor device. Accordingly, the embodiment can stably attach the semiconductor device to the circuit board, and thus improve mechanical reliability and electrical reliability between the circuit board and the semiconductor device. Furthermore, the embodiment can stably operate the semiconductor device, and thereby improve operational reliability of electronic products such as servers to which the semiconductor package is applied.

Furthermore, the protective layer, the conductive bonding part, and the semiconductor device are provided with different materials, and thus have different coefficients of thermal expansion. Therefore, due to a difference in the coefficient of thermal expansion between them, the thermal deformation of the protective layer having a relatively large coefficient of thermal expansion may be the largest. At this time, the embodiment can minimize thermal deformation such as expansion and/or contraction of the protective layer by providing a plurality of concave surfaces that buffer thermal deformation in the protective layer, thereby improving the mechanical reliability and/or electrical reliability of the semiconductor package.

In addition, the concave surface provided in the protective layer has a rounded surface from an upper surface to a lower surface of the protective layer. Through this, the embodiment can further improve an effect of preventing stress action by the concave surface. For example, when the concave surface has an angular square shape, stress may be concentrated at an angular portion of the concave surface, which may cause a problem of deterioration in mechanical reliability or electrical reliability. In contrast, the embodiment can provide the concave surface with a rounded surface, thereby preventing stress from being concentrated at a specific portion of the concave surface. Therefore, the embodiment can further improve the physical reliability and/or electrical reliability of the semiconductor package.

Meanwhile, the protective layer includes a plurality of first concave surfaces that overlap with the connection member in the vertical direction and a plurality of second concave surfaces that do not overlap with the connection member in the vertical direction. At this time, a width of the first concave surface in a horizontal direction is different from a width of the second concave surface in a horizontal direction. That is, the width of the first concave surface in the horizontal direction is smaller than the width of the second concave surface in the horizontal direction. Through this, the embodiment can prevent a height deviation between the plurality of conductive bonding parts by the first concave surface and the second concave surface, and further prevent a contact area between the through electrode of the conductive bonding part and the protective layer from being reduced. Therefore, the embodiment can improve the mechanical reliability and/or the electrical reliability of the semiconductor package. In addition, the embodiment can increase a surface area of the protective layer by making the width of the second concave surface larger than the width of the first concave surface, compared to a case where the width of the second concave surface is the same as the width of the first concave surface, and can maximize the effect of preventing stress due to thermal deformation.

In addition, the concave surface provided in the protective layer can solve an electrical short-circuit problem that may occur due to the contact part expanding in the horizontal direction according to the heat and pressure applied to the contact part. For example, when the contact part expands in the horizontal direction as the heat and pressure are applied to the contact part, the concave surface of the protective layer can function as a dam that prevents the expansion and movement of the contact part. Through this, the embodiment can further improve the electrical reliability of the semiconductor package.

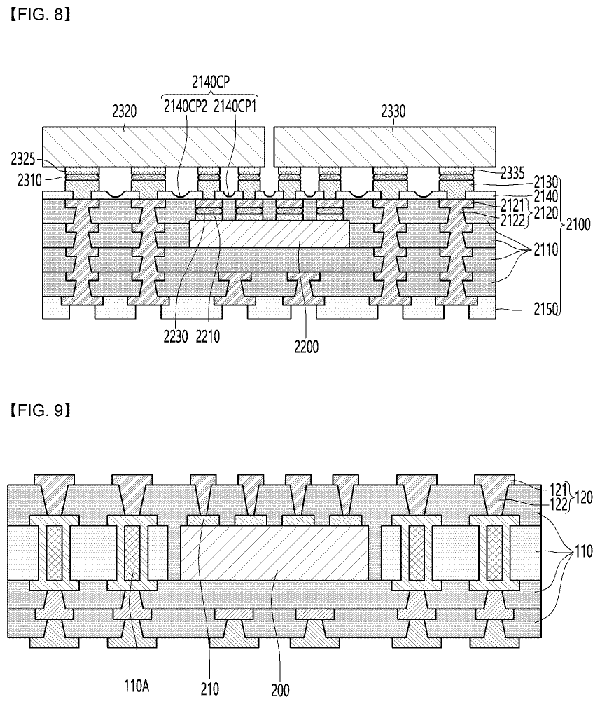

FIGS. 9 to 17 are drawings showing a method of manufacturing the semiconductor package shown in FIG. 1 in order of processes.

Referring to FIG. 9, the embodiment performs a process of preparing an insulating layer 110, a process of forming a cavity in the insulating layer 110, a process of embedding a connection member 200 in the cavity of the insulating layer 110, and a process of forming an electrode part 120 in the insulating layer 110.

Next, referring to FIG. 10, the embodiment performs a process of forming a dry film DF to form a through hole 140TH of the first protective layer 140.

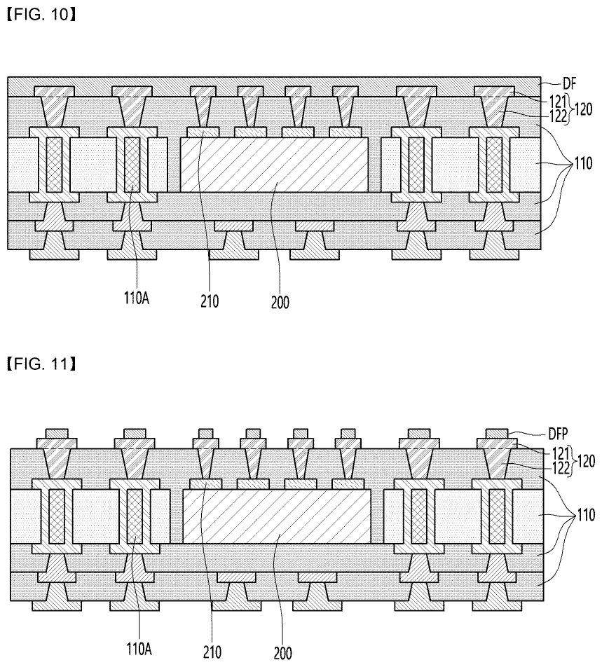

Next, referring to FIG. 11, the embodiment performs a process of forming a dry film pattern DFP by exposing and developing the dry film DF. The dry film pattern DFP is disposed on the electrode part 130 corresponding to a region where the through hole 140TH of the first protective layer 140 is to be formed.

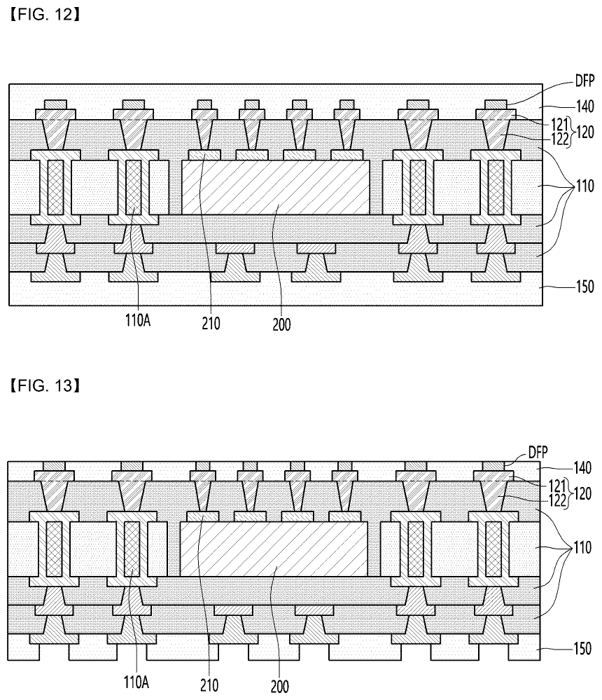

Next, referring to FIG. 12, the embodiment performs a process of forming a first protective layer 140 covering a dry film pattern DFP on an insulating layer 110. In addition, the embodiment performs a process of forming a second protective layer 150 under the insulating layer 110.

Next, referring to FIG. 13, the embodiment performs a process of etching the first protective layer 140 to reduce a thickness of the first protective layer 140. For example, the embodiment may etch the first protective layer 140 so that the thickness of the first protective layer 140 is less than or equal to the dry film pattern DFP.

In addition, the embodiment may perform a process of exposing and developing the second protective layer 150 to form a through hole in the second protective layer 150.

Next, referring to FIG. 14, a process of partially etching an upper surface of the first protective layer 140 to form a concave surface 140CP is performed. At this time, the concave surface 140CP may be formed in multiple numbers while being spaced apart from the through hole 140TH provided in the first protective layer 140 by a certain spacing in the horizontal direction.

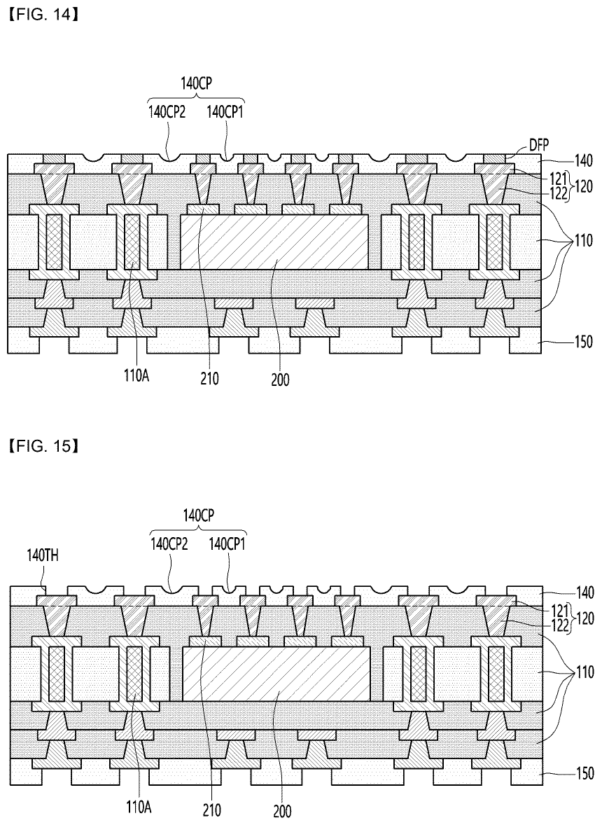

Next, referring to FIG. 15, the embodiment performs a process of removing the dry film pattern DFP. Through this, a through hole 140TH corresponding to a position where the dry film pattern DFP is removed may be formed in the first protective layer 140.

Through this, the embodiment may form a through hole 140TH and a concave surface 140CP in the first protective layer 140.

However, the embodiment may form the through hole 140TH and the concave surface 140CP in the first protective layer 140 by a process other than the process illustrated in FIGS. 9 to 15.

For example, the embodiment may perform a process of forming the through hole 140TH by exposing and developing the first protective layer 140. In addition, after the through hole 140TH is formed, a process of partially etching the upper surface of the first protective layer 140 to form the concave surface 140CP may be performed.

For another example, the embodiment may form the through hole 140TH or the concave surface 140CP by processing the first protective layer 140 by a first method, and may form the concave surface 140CP or the through hole 140TH by processing the first protective layer by a second method different from the first method. For example, the first method may be a laser method, and the second method may be a photolithography process.

Next, referring to FIG. 16, the embodiment performs a process of forming a conductive bonding part 130 including a through electrode disposed in a through hole 140TH of a first protective layer 140 and a protruding electrode disposed on the through electrode. At this time, the embodiment may form a concave surface 140CP on the upper surface of the first protective layer 140 by considering the width of a protruding electrode of the conductive bonding part 130.

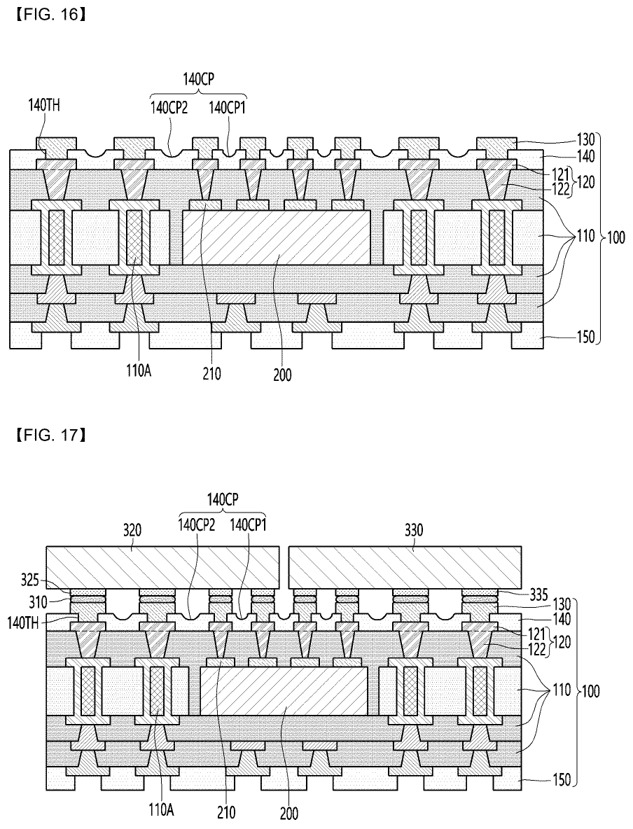

Next, referring to FIG. 17, the embodiment performs a process of disposing a contact part 310 on the conductive bonding part 130. Thereafter, the embodiment performs a process of mounting a semiconductor devices 320 and 330 on the contact part 310. Through this, the embodiment can mount a semiconductor devices 320 and 330 facing the concave surface 140CP of the first protective layer 140 on the conductive bonding part 130.

On the other hand, when the circuit board having the above-described characteristics of the invention is used in an IT device or home appliance such as a smart phone, a server computer, a TV, and the like, functions such as signal transmission or power supply can be stably performed. For example, when a circuit board having the features of the present invention performs a semiconductor package function, the circuit board can function to safely protect the semiconductor chip from external moisture or contaminants, or alternatively, it is possible to solve problems of leakage current, electrical short circuit between terminals, and electrical opening of terminals supplied to the semiconductor chip. In addition, when the function of signal transmission is in charge, it is possible to solve the noise problem. Through this, the circuit board having the above-described characteristics of the invention can maintain the stable function of the IT device or home appliance, so that the entire product and the circuit board to which the present invention is applied can achieve functional unity or technical interlocking with each other.

When the circuit board having the characteristics of the invention described above is used in a transport device such as a vehicle, it is possible to solve the problem of distortion of a signal transmitted to the transport device, or alternatively, the safety of the transport device can be further improved by safely protecting the semiconductor chip that controls the transport device from the outside and solving the problem of leakage current or electrical short between terminals or the electrical opening of the terminal supplied to the semiconductor chip. Accordingly, the transportation device and the circuit board to which the present invention is applied can achieve functional integrity or technical interlocking with each other.

The characteristics, structures and effects described in the embodiments above are included in at least one embodiment but are not limited to one embodiment. Furthermore, the characteristics, structures, and effects and the like illustrated in each of the embodiments may be combined or modified even with respect to other embodiments by those of ordinary skill in the art to which the embodiments pertain. Thus, it should be construed that contents related to such a combination and such a modification are included in the scope of the embodiment.

The above description has been focused on the embodiment, but it is merely illustrative and does not limit the embodiment. A person skilled in the art to which the embodiment pertains may appreciate that various modifications and applications not illustrated above are possible without departing from the essential features of the embodiment. For example, each component particularly represented in the embodiment may be modified and implemented. In addition, it should be construed that differences related to such changes and applications are included in the scope of the embodiment defined in the appended claims.

1. A circuit board comprising:
an insulating layer;
an electrode part disposed on the insulating layer;
a protective layer disposed on the electrode part; and
a plurality of conductive bonding parts disposed on the protective layer,
wherein each of the plurality of conductive bonding parts includes a through electrode penetrating the protective layer,
wherein an upper surface of the protective layer includes a concave surface provided between the plurality of through electrodes,
wherein a separation distance in a vertical direction between the concave surface and the electrode part is smaller than a thickness of at least one through electrode among the plurality of through electrodes.

2. The circuit board of claim 1, wherein each of the plurality of conductive bonding parts further includes a protruding electrode disposed on the through electrode.

3. The circuit board of claim 2, wherein a width of the concave surface in a horizontal direction is smaller than a separation spacing between the plurality of protruding electrodes.

4. The circuit board of claim 3, wherein the concave surface does not overlap with each of the protruding electrodes of the plurality of conductive bonding parts in the vertical direction.

5. The circuit board of claim 2, wherein a width of the concave surface in a horizontal direction is equal to a separation spacing between the plurality of protruding electrodes.

6. The circuit board of claim 2, wherein a width of the concave surface in a horizontal direction is greater than a separation spacing between the plurality of protruding electrodes.

7. The circuit board of claim 6, wherein the width of the concave surface in the horizontal direction is equal to the separation spacing between the plurality of through electrodes.

8. The circuit board of claim 7, wherein a protruding electrode of each of the plurality of conductive bonding parts includes a convex part overlapping the concave surface in the vertical direction and corresponding to the concave surface.

9. The circuit board of claim 1, wherein the concave surface includes a rounded surface from an upper surface to a lower surface of the protective layer.

10. The circuit board of claim 1, wherein a depth of the concave surface is smaller than the thickness of the through electrode.

11. The circuit board of claim 1, wherein a depth of the concave surface is same as the thickness of the through electrode.

12. The circuit board of claim 1, wherein a depth of the concave surface is greater than the thickness of the through electrode, and
wherein at least a portion of the concave surface is positioned lower than the upper surface of the electrode part.

13. The circuit board of claim 1, further comprising:
a connection member embedded in the insulating layer,
wherein the concave surface includes a first concave surface overlapped with the connection member in the vertical direction; and a second concave surface that does not overlap with the connection member in the vertical direction, and
wherein the first and second concave surfaces have different widths in a horizontal direction.

14. The circuit board of claim 13, wherein a width of the first concave surface in the horizontal direction is smaller than a width of the second concave surface in the horizontal direction.

15. The circuit board of claim 14, wherein at least a part of the electrode part is embedded in the insulating layer, and
wherein a contact member is embedded in the insulating layer and disposed between the electrode part and a pad part of the connection member.

16. A semiconductor package comprising:
an insulating layer;
an electrode part disposed on the insulating layer;
a protective layer disposed on the electrode part;
a plurality of conductive bonding parts disposed on the protective layer;
a contact part disposed on the plurality of conductive bonding parts; and
a semiconductor device disposed on the contact part,
wherein each of the plurality of conductive bonding parts includes a through electrode penetrating the protective layer,
wherein an upper surface of the protective layer includes a concave surface provided between the plurality of through electrodes,
wherein a separation distance in a vertical direction between the concave surface and the electrode part is smaller than a thickness of at least one through electrode among the plurality of through electrodes, and
wherein the concave surface overlaps the semiconductor device in the vertical direction.

17. The semiconductor package of claim 16, further comprising:
a connection member embedded in the insulating layer,
wherein the semiconductor device includes a first semiconductor device including a first terminal overlapping the connection member in the vertical direction, and a second semiconductor device including a second terminal spaced from the first semiconductor device in a horizontal direction and overlapping the connection member in the vertical direction.

18. The semiconductor package of claim 17, wherein the concave surface includes a first concave surface overlapping the connection member in the vertical direction, and a second concave surface not overlapping the connection member in the vertical direction, and
wherein the first and second concave surfaces have different widths in the horizontal direction.

19. The semiconductor package of claim 18, wherein a width of the first concave surface widths in the horizontal direction is smaller than a width of the second concave surface widths in the horizontal direction.

20. The semiconductor package of claim 19, wherein at least a part of the electrode part is embedded in the insulating layer, and
wherein a contact member is embedded in the insulating layer and disposed between the electrode part and a pad part of the connection member.
